(19) United States
(12) Patent Application Publication
(10) Pub. No.: US 2017/0053832 A1
(43) Pub. Date: Feb. 23, 2017

(54) WAFER STRUCTURE AND PROCESSING METHOD THEREOF

(71) Applicant: Beijing Acuti Microsystems Co., Ltd., Beijing (CN)

(72) Inventors: Caixin Wan, Beijing (CN); Jason Zhu, Beijing (CN)

(21) Appl. No.: 15/241,956

(22) Filed: Aug. 19, 2016

(30) Foreign Application Priority Data
Aug. 20, 2015 (CN) 201510516062.2
Oct. 21, 2015 (CN) 201520820333.9
May 18, 2016 (CN) 201620455672.6

(51) Int. Cl. H01L 21/78; H01L 21/268; H04R 7/16; H04R 19/04; H04R 19/00; H01L 23/544; H01L 21/66

(52) U.S. Cl. CPC H01L 21/78; H01L 23/544; H01L 21/268; H01L 22/14; H04R 19/04; H04R 19/005; H04R 7/16; H01L 2223/5446; H04R 2201/003

(57) ABSTRACT

A wafer structure and a processing method of a wafer structure are disclosed here. The wafer structure, which is used for forming a plurality of dies, comprising: a semiconductor substrate having a first surface and a second surface opposite to the first one; at least one first functional layer and at least one second functional layer at the first surface of the semiconductor substrate, wherein the at least one second functional layer is located in a scribe lane of the wafer; and a plurality of scribing marks in the scribe lane, for singulating adjacent ones of the plurality of dies during a laser cutting process, wherein the plurality of dies each include the at least one first functional layer and a portion of the semiconductor substrate. The wafer structure can provide a functional layer in the scribe lane, while it facilitates to singulate the adjacent ones of the plurality of dies.

### CROSS-REFERENCE TO RELATED APPLICATION

This application claims the benefits of Chinese Patent Application No. 201510516062.2, filed on Aug. 20, 2015, Chinese Patent Application No. 201520820333.9, filed on Oct. 21, 2015, and Chinese Patent Application No. 201620455672.6, filed on May 18, 2016, all of which are incorporated herein by reference in its entirety.

### BACKGROUND OF THE DISCLOSURE

Field of the Disclosure

The present invention generally relates to the field of semiconductor fabrication, and more particularly, to a wafer structure and a processing method thereof.

Background of the Disclosure

The process of semiconductor integrated circuits generally includes wafer fabrication, wafer testing, wafer dicing, packaging and final testing. A wafer is a slice of crystal used for semiconductor integrated circuits fabrication, which is typically has a circular shape. Wafers are available in a variety of diameters such as 6 inches, 8 inches or 12 inches. A plurality of dies are produced in an array by a functional layer, where the functional layer which is formed on the wafer, consists of stacked insulating films and functional films. Then, an electrical test is performed on the plurality of dies at a step of wafer testing, singulating the qualified dies by sawing on the wafer after weeding out the defective dies. Packaging is the next step for assembling the qualified dies into chips by packing and wire bonding, after this, another electrical testing is necessary for ensuring the quality of the integrated circuits.

Forming the plurality of dies on each wafer will generate a batch of products with good performance consistency, and will also reduce the manufacturing costs significantly. Thus, the wafer dicing is an essential step for modern semiconductor processing. The process of the wafer dicing include mechanical cutting and laser cutting. A scribe lane is preformed between the adjacent ones of the plurality of the dies. During the mechanical cutting, cut the wafer along the scribe lane by a cutting wheel or a blade, most portions of the material in the scribe lane are removed. Because of the wear debris generated by the mechanical cutting, it is necessary to clean and remove the wear debris when performing the mechanical cutting. During the laser cutting, an modified layer is formed by focusing the laser inside the wafer through its top surface, in order to provide the initial cracks, then scan the laser along the scribe lane, forming an adhesive film on the bottom surface of the wafer, and then extend the adhesive film to separate the adjacent ones of the plurality of dies.

Compared with the mechanical cutting, the laser cutting will not generate the wear debris, thereby reducing the number of the processing steps. The laser cutting will achieve high precision by simply providing narrow scribe lines, thus the utilization rate of the wafer is improved. The disadvantage of the laser cutting is that the functional layers on the wafer are hard to be penetrated. In the wafer testing, the connections among the plurality of the dies can be provided by the functional layer in the scribe lane, for implementing the testing on the plurality of dies connected in series or in parallel. However, if the functional layer is formed in the scribe lane, it will be difficult to form the initial cracks continuously in the scribing line due to the blocking by the functional layer, which will lead to a failure on die singulation and even cause damages to the dies.

Therefore, it is expected to design a new scribe lane, so that the plurality of the dies connected with each other through the functional layer of the scribe lane can be separated.

### SUMMARY OF THE DISCLOSURE

In view of this, one object of the present disclosure is to provide a wafer processing method and a wafer structure, where the wafer structure includes a functional layer and facilitates laser cutting.

According to an aspect of the invention, there is provided a wafer structure, which is used for forming a plurality of dies, comprising: a semiconductor substrate; at least one first functional layer and at least one second functional layer at a first surface of the semiconductor substrate, wherein the at least one second functional layer is located in a scribe lane of the wafer; and a plurality of scribing marks in the scribe lane, wherein the plurality of dies each include the at least one first functional layer and a portion of the semiconductor substrate, the plurality of scribing marks are used for singulating adjacent ones of the plurality of dies during a laser cutting process.

Preferably, the at least one second functional layer provides mechanical and/or electric connection between the adjacent ones the plurality of dies.

Preferably, the plurality scribing marks are located below the at least one second functional layer.

Preferably, the plurality scribing marks are located between adjacent ones of the at least one second functional layer of adjacent ones of the plurality of dies.

Preferably, the adjacent ones of the at least one second functional layer in the adjacent ones of the plurality of dies are separated from each other with a distance no less than 5 micrometers.

Preferably, the plurality of the scribing marks are a plurality of trenches opened at the first surface, each of the at least one second functional layer covers at least a portion of the plurality of trenches.

Preferably, the plurality of the scribing marks are a plurality of trenches opened at the second surface.

Preferably, the plurality of trenches extend in the same direction as a laser scanning direction.

Preferably, the trenches have a length no less than a dimension of respective one of the at least one second functional layer along the laser scanning direction.

Preferably, the plurality of the trenches have a width less than 5 micrometers.

Preferably, the trenches reach the same depth as a focus depth of the laser during scanning in the semiconductor substrate.

Preferably, the plurality of the scribing marks are openings which extend from a first surface to a second surface of the semiconductor substrate.

Preferably, the at least one first functional layer and the at least one second functional layer includes a common first sacrificial layer.

Preferably, the plurality of the scribing marks are located below the first sacrificial layer.

Preferably, the first sacrificial layer has a thickness in a range between 0.5 micrometer and 5 micrometers.

Preferably, the plurality of the scribing marks have an overall length along the scribe lane, the proportion of which in a length of the scribe lane is no more than 50%.

Preferably, the plurality of the scribing marks have a width in a range between 5 micrometers and 120 micrometers.

Preferably, the at least one first functional layer is separated by the scribe lane.

Preferably, the plurality of dies are MEMS microphones respectively, and the at least one second functional layer further includes a second sacrificial layer, a diaphragm and a back electrode, the first sacrificial layer provides an anchor for securing the diaphragm, the second sacrificial layer separating the diaphragm from the back electrode, and in the semiconductor substrate, and an acoustic cavity is formed in the semiconductor substrate and extends from the second surface to the diaphragm.

Preferably, the scribing marks are formed simultaneously with the acoustic cavity.

According to another aspect of the invention, there is provided a processing method of a wafer structure, comprising: forming a plurality of dies, each of which includes a portion of the semiconductor substrate and respective one of at least one first functional layer formed at a first surface of the semiconductor substrate; forming at least one second functional layer in the scribe lane for providing mechanical and/or electric connection between adjacent ones of the plurality of dies; forming scribing marks in the scribe lane; and performing laser cutting along the scribe lane.

Preferably, the plurality of scribing marks include a plurality of trenches which are opened at the first surface, wherein the second functional layer is formed after the plurality of scribing marks so that the at least one second functional layer covers at least a portion of the plurality of trenches respectively.

Preferably, the plurality of scribing marks include a plurality of trenches which are opened at a second surface of the semiconductor substrate, wherein the second surface is opposite to the first surface.

Preferably, the at least one first functional layer and the at least one second functional layer includes a common first sacrificial layer, the plurality of scribing marks include a plurality of openings which are formed by etching to extend from the first surface to the second surface of the semiconductor substrate while the first sacrificial layer is used as an etch stop.

Preferably, when forming the plurality of scribing marks, an acoustic cavity is formed simultaneously in the semiconductor substrate by etching while the first sacrificial layer is used as an etch stop.

Preferably, the laser cutting comprises: attaching an adhesive film to the second surface of the semiconductor substrate; performing laser scanning along the scribing line on the first surface of the semiconductor substrate so that a modified layer is formed in the semiconductor substrate; and expanding the adhesive film to separate adjacent ones of the plurality of dies.

Preferably, the laser cutting is performed along an extension direction of the plurality of scribing marks.

Preferably, the laser scanning is performed along the scribe lane for several times, to have different focus depths in the semiconductor substrate each time.

Preferably, at least one of the different focus depths reaches a depth of the plurality of scribing marks.

Preferably, an modified layer is formed by laser scanning for providing initial cracks which form a complete path with the plurality of the scribing marks.

Preferably, before the step of forming the at least one second functional layer and the step of performing laser cutting, the method further comprises testing the wafer while the at least one second functional layer provides connections among the plurality of dies in series or in parallel.

According to the wafer structure and the processing method of a wafer structure related to an embodiment of the present invention, a plurality of the scribing marks are provided for singulating adjacent ones of the plurality of the dies during laser cutting. The wafer structure allows the functional layer to be provided in the scribe lane, and facilitates to singulate the adjacent ones of the plurality of dies. The functional layer may, for example, avoid additional testing interconnections inside the dies, thus improving the dies utilization rate and reducing the cost.

In the preferred embodiment, before performing the laser cutting, the at least one second functional layer provides the connections among the adjacent dies in order to implement a testing on the plurality of dies connected in series or in parallel. After the wafer testing, the plurality of the dies are singulated along a complete path consisting of the scribing marks and the initial cracks, where the initial cracks are formed by the laser scanning. Then, the singulated dies are packaged as individual products.

In the preferred embodiment, the wafer structure forms the scribing marks in the scribe lane below the functional layer, so that a substantially complete path is generated by the plurality of the scribing marks and the initial cracks, where the initial cracks are formed by the laser scanning. Thus, the adjacent ones of the dies will be singulated by laser cutting conveniently and the die yield will be improved.

In the preferred embodiment, the first sacrificial layer is used for improving the intensity of the wafer structure in manufacturing process, thus protecting the wafer structure and the manufacturing equipment.

In the preferred embodiment, the scribing marks with predetermined width and length reduces the frequency of self-testing alignment accuracy in the dicing equipment and thus reducing the manufacturing costs and the die costs.

In the preferred embodiment, the scribing marks and the acoustic cavity are formed simultaneously in the semiconductor substrate, by selectively etching over a first sacrificial layer having a predetermined thickness. The portion of the first sacrificial layer above the scribing marks remains after etching, for providing strength of the dies after the laser cutting. The thickness of the first sacrificial layer is controlled in a predetermined range to prevent the wafer structure from breaking during processing and transporting, and to prevent the wafer structure from distortion due to a too large thickness of the first sacrificial layer. Thus, a higher die yield is obtained.

### BRIEF DESCRIPTION OF THE DRAWINGS

The above and other objects, advantages and features of the present invention will become more fully understood from the detailed description given hereinbelow in connection with the appended drawings, and wherein:

FIG. 1a to FIG. 1c illustrate schematic diagrams of a conventional wafer structure in a perspective view, in a top view and in a cross-sectional view, respectively.

FIG. 2a to FIG. 2c illustrate schematic diagrams of a wafer structure according to a first embodiment of the disclosure in a perspective view, in a top view and in a cross-sectional view, respectively.

FIG. 3a to FIG. 3c illustrate schematic diagrams of a wafer structure according to a second embodiment of the disclosure in a perspective view, in a top view and in a cross-sectional view, respectively.

FIG. 4 illustrates a schematic diagram of a wafer structure under laser irradiation according to a second embodiment of the disclosure in a cross-sectional view.

FIG. 5a to FIG. 5c illustrate schematic diagrams of a wafer structure according to a third embodiment of the disclosure in a perspective view, in a top view and in a cross-sectional view, respectively.

FIG. 6a to FIG. 6c illustrate schematic diagrams of a wafer structure according to a forth embodiment of the disclosure in a perspective view, in a top view and in a cross-sectional view, respectively.

FIG. 7 illustrates a schematic diagram of a wafer structure under laser irradiation according to a third embodiment of the disclosure in a cross-sectional view.

FIG. 8a to FIG. 8c is a perspective view, a top view and a cross-sectional view respectively showing a wafer structure after forming the scribing marks, according to a fifth embodiment of the disclosure.

FIG. 9a to FIG. 9c is a perspective view, a top view and a cross-sectional view respectively showing a wafer structure after releasing structure, according to a fifth embodiment of the disclosure.

FIG. 10a to FIG. 10c is a perspective view, a top view and a cross-sectional view respectively showing a wafer structure under laser irradiation, according to a fifth embodiment of the disclosure.

FIG. 11 illustrates a schematic diagram of a wafer structure under laser irradiation according to a fifth embodiment of the disclosure in a cross-sectional view.

### DETAILED DESCRIPTION OF THE DISCLOSURE

Exemplary embodiments of the present disclosure will be described in more details below with reference to the accompanying drawings. In the drawings, like reference numerals denote like members. The figures are not drawn to scale, for the sake of clarity. Moreover, some well-known parts may not be shown.

It should be understood that when one layer or region is referred to as being “above” or “on” another layer or region in the description of a structure, it can be directly above or on the other layer or region, or other layers or regions may be intervened therebetween. Moreover, if the device in the figures is turned over, the layer or region will should be “under” or “below” the other layer or region. In contrast, when one layer is referred to as being “directly on” or “on and adjacent to” or “adjoin” another layer or region, there are not intervening layers or regions present.

In the following description that the terms such as “first”, “second” and the like are used herein for purposes of description and are not intended to indicate or imply relative importance or significance. The term “plurality”, as used herein, is defined as two or more than two, unless something otherwise is specifically stated. In the present application, the term “wafer structure” is a semiconductor structure formed by a wafer, comprising a semiconductor substrate and a functional layer, wherein the wafer is mainly used to provide a substrate for semiconductor devices.

The disclosure can be embodied in various forms, some of which will be described below.

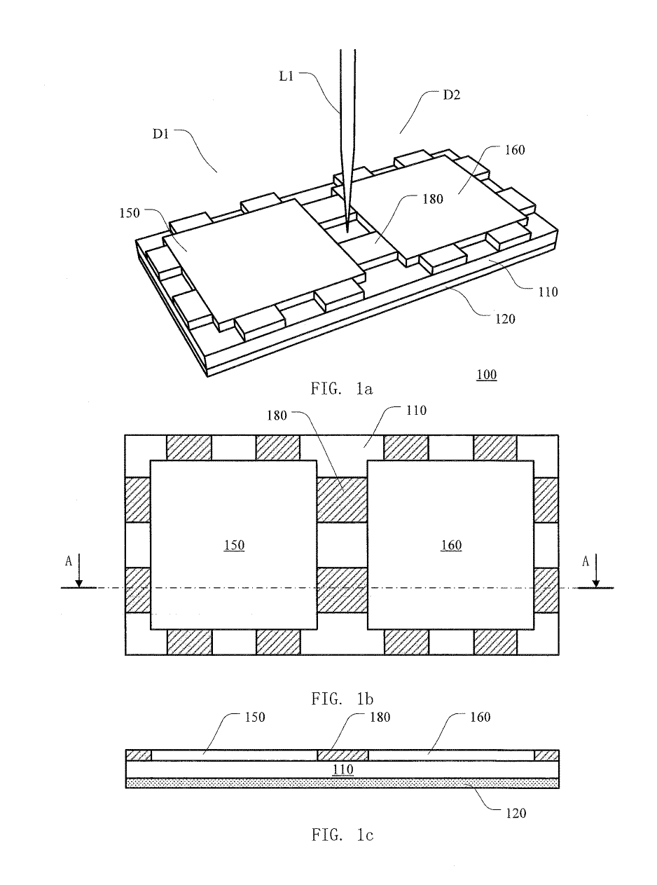

FIG. 1a to FIG. 1c illustrate schematic diagrams of a conventional wafer structure in a perspective view, in a top view and in a cross-sectional view, respectively. The cross sectional view shown in FIG. 1b is taken along the line AA indicated in the cross-sectional view shown in FIG. 1c.

As illustrated as FIG. 1a to FIG. 1c, the wafer structure 100 comprises a semiconductor substrate 110 with a plurality of functional layers 150, 160 and 180 on its first surface, and an adhesive film 120 on the second surface of the semiconductor substrate 110, where the second surface is opposite to the first surface of the semiconductor substrate 110. The wafer structure 100 provides two dies D1 and D2 which are separated by a scribe lane, wherein the die D1 comprises the functional layer 150 and a portion of the semiconductor substrate 110, and the die D2 comprises the functional layer 160 and another portion of the semiconductor substrate 110. The functional layer 180 is used for providing a plurality of interconnections between the die D1 and the die D2.

Typically, the functional layers can be formed by stacking a plurality of insulating films with a plurality of metal films. In different types of the die D1 and the die D2, the plurality of the functional layers 150, 160 and 180 have different structures. For example, the die D1 and the die D2 can include analog or digital circuits, wherein the functional layers form at least a portion of the transistor structure. The insulating films are used as interlayer dielectric of the transistor. The metal films form contacts and conductive vias for the active region. The die D1 and the die D2 may also be micro-electromechanical systems (MEMS) chips, such as an MEMS microphone, wherein the functional layer forms the MEMS structure. The insulating films form the sacrificial layer and the anchor of the MEMS microphone, while the metal layers form the diaphragm and the back electrode of the MEMS microphone.

When the die D1 and the die D2 are used as MEMS microphones, each die corresponds to one MEMS microphone. The functional layer 180 is used for providing a common anchor for both the die D1 and the die D2, or providing electrical connections for the wafer testing. During the wafer testing, the functional layers in the scribe lane can provide connections among the plurality of dies to achieve a testing on dies in series or in parallel. After completing the wafer testing, separate the die D1 and the die D2 by the laser cutting, then package them into singulated products.

During the laser cutting, initial cracks are generated in a modified layer, by focusing the laser L1 inside the semiconductor substrate 110 from the top surface of the wafer structure 100. The laser L1 scans along the scribing line. The incident energy of the laser L1 is scattered out due to the functional layer 180 in the scribe lane, therefore it is difficult for the laser L1 to reach below the functional layer 180. As a result, the continuous initial cracks can hardly be formed in the scribe lane. When expanding the adhesive film 120, the initial cracks are interrupted at the bottom of the function layer 180, which may fail the singulation of the die D1 and the die D2, even cause damages on the die D1 and the die D2.

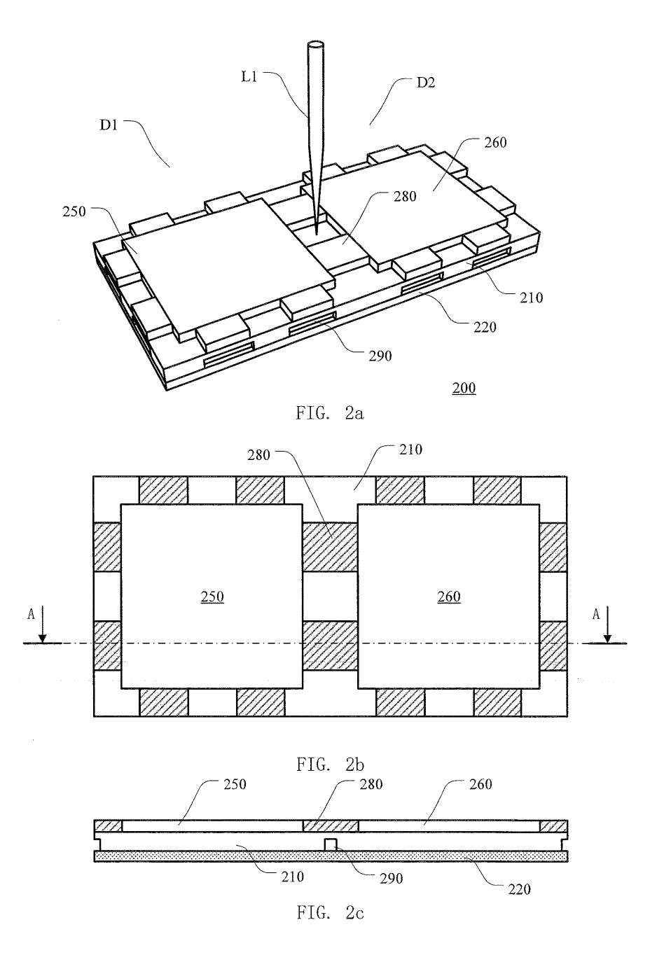

FIG. 2a to FIG. 2c illustrate schematic diagrams of a wafer structure according to a first embodiment of the disclosure in a perspective view, in a top view and in a cross-sectional view, respectively. The cross sectional view shown in FIG. 2b is taken along the line AA indicated in the cross-sectional view shown in FIG. 2c.

As illustrated as FIG. 2a to FIG. 2c, the wafer structure 200 comprises a semiconductor substrate 210 with a plurality of functional layers 250, 260 and 280 on its first surface, and an adhesive film 220 on the second surface of the semiconductor substrate 210, where the second surface is opposite to the first surface of the semiconductor substrate 210. The wafer structure 200 provides two dies D1 and D2 which are separated by a scribe lane, wherein the die D1 comprises the functional layer 250 and a portion of the semiconductor substrate 210, and the die D2 comprises the functional layer 260 and another portion of the semiconductor substrate 210. The functional layer 280 is used for providing a plurality of interconnections between the die D1 and the die D2.

When the die D1 and the die D2 are used as MEMS microphones, each die corresponds to one MEMS microphone. The functional layer 280 is used for providing a common anchor for both the die D1 and the die D2, or providing electrical connections for the wafer testing. During the wafer testing, the functional layers in the scribe lane can provide connections among the plurality of dies to implement a testing on dies in series or in parallel. After completing the wafer testing, do the laser cutting to separate the die D1 and the die D2, then package them into singulated products.

Different from the wafer structure 100 according to the prior art shown in FIG. 1a to FIG. 1c, the wafer structure 200 of this embodiment further includes a plurality of scribing marks 290, which are the trenches opened at the second surface of the semiconductor substrate 210. The plurality of scribing marks 290 are located below the functional layer 280, and extended in the same direction as the laser scanning Preferably, the extension length of the scribing marks 290 is greater than the width of the corresponding functional layer 280.

In one example, the trenches with predetermined depth may be formed by the mechanical cutting at a predetermined position at the second surface of the semiconductor substrate 210. In another example, the scribing marks may be formed by etching. For defining the position of the trenches, a photoresist mask may be used for forming the openings corresponding to the trenches. Then, a portion of the semiconductor substrate is removed through the photoresist mask by dry etching, such as ion milling etching, plasma etching, reactive ion etching, laser ablation, or by wet etching using an etching solution, so as to form the trenches with predetermined depth. After etching, the photoresist mask is removed by ashing or dissolution with a solvent.

During the laser cutting, the initial cracks are generated in a modified layer, by focusing the laser L1 inside the semiconductor substrate 210 from the top surface of the wafer structure 200. The laser L1 scans along the scribing line. Due to the functional layer 280 in the scribe lane, the laser L1 can hardly reach below the functional layer 280, thus forming discontinuous initial cracks along the scribe lane. In this embodiment, the trench depth of the scribing marks 290 reaches the same level as the initial cracks formed by the laser L1, thereby a complete path may still be formed by the connections among the discontinuous initial cracks and the trench of the scribe marks 290. While expanding the adhesive film 220, the initial cracks together with the scribing marks 290 provide the extension path of cracks, thereby singulating the die D1 and the die D2.

In this embodiment, the scribing marks 290 and the initial cracks formed by the laser L1 generate a complete path having a width, for example, less than 5 micrometers, to avoid breaks causing by the trenches with an overlarge opening size of the scribing marks 290.

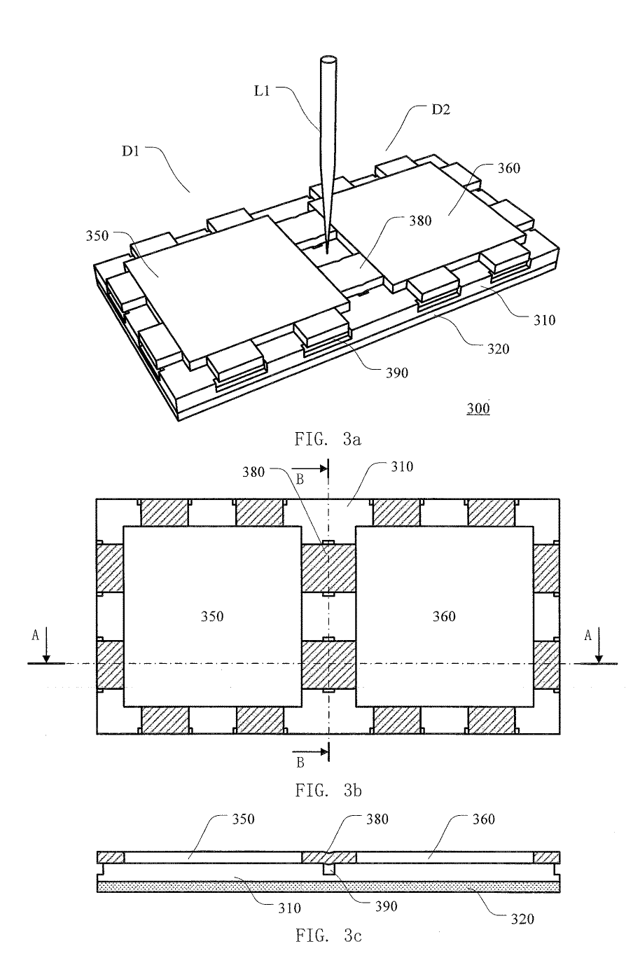

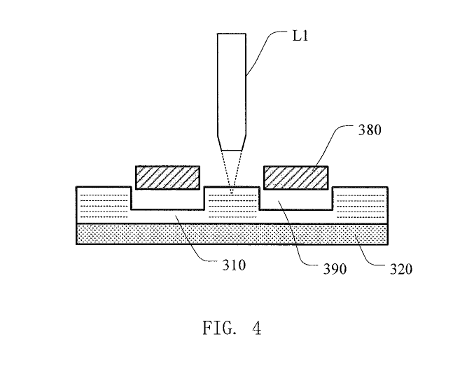

FIG. 3a to FIG. 3c illustrate schematic diagrams of a wafer structure according to a second embodiment of the disclosure in a perspective view, in a top view and in a cross-sectional view, respectively. The cross sectional view shown in FIG. 3b is taken along the line AA indicated in the cross-sectional view shown in FIG. 3c, and the cross sectional view shown in FIG. 4 is taken along the line BB.

As illustrated as FIG. 3a to FIG. 3c, the wafer structure 300 comprises a semiconductor substrate 310 with a plurality of functional layers 350, 360 and 380 on its first surface, and an adhesive film 320 on the second surface of the semiconductor substrate 310, where the second surface is opposite to the first surface of the semiconductor substrate 310. The wafer structure 300 provides two dies D1 and D2 which are separated by a scribe lane, wherein the die D1 comprises the functional layer 350 and a portion of the semiconductor substrate 310, and the die D2 comprises the functional layer 360 and another portion of the semiconductor substrate 310. The functional layer 380 is used for providing a plurality of interconnections between the die D1 and the die D2.

Different from the wafer structure 100 according to the prior art shown in FIG. 1a to FIG. 1c, the wafer structure 300 of this embodiment further includes a plurality of scribing marks 390. Different from the wafer structure 200 according to the first embodiment of this invention shown in FIG. 2a to FIG. 2c, the plurality of scribing marks 390 are the trenches opened at the first surface of the semiconductor substrate 310, located below the functional layer 380 and extended in the same direction as the laser scanning Preferably, the extension length of the scribing marks 390 is greater than the width of the corresponding functional layer 380.

The other aspects of the wafer structure 300 in this embodiment are the same as the wafer structure 200 described in the first embodiment shown in FIG. 2a to FIG. 2c, thus no detailed description is repeated here.

FIG. 4 illustrates a schematic diagram of a wafer structure under laser irradiation according to a second embodiment of the disclosure in a cross-sectional view. As shown in FIG. 4, along the scanning path of the laser L1, the laser L1 cannot reach the semiconductor substrate 310 due to the blocking by the functional layer 380 which located upon the semiconductor substrate 310. Therefore, the initial cracks are discontinuous, shown as the dashed line.

During laser irradiating, the laser scanning can be performed along the scribe lane for a plurality of times, for focusing the laser L1 at different depths in the semiconductor substrate 310 respectively, thereby forming the initial cracks with a plurality of different depths extending along the scribe lane. In this embodiment, the initial cracks with at least one depth can meet the scribing marks 390, thereby a complete path is formed by the connections among them. Preferably, the trenches of the scribing marks 390 have the same depth as the maximum focus depth of the plurality of the laser scannings, thereby the mechanical strength of the wafer structure can be kept before laser cutting, and the singulated positions of the adjacent dies can also be controlled accurately.

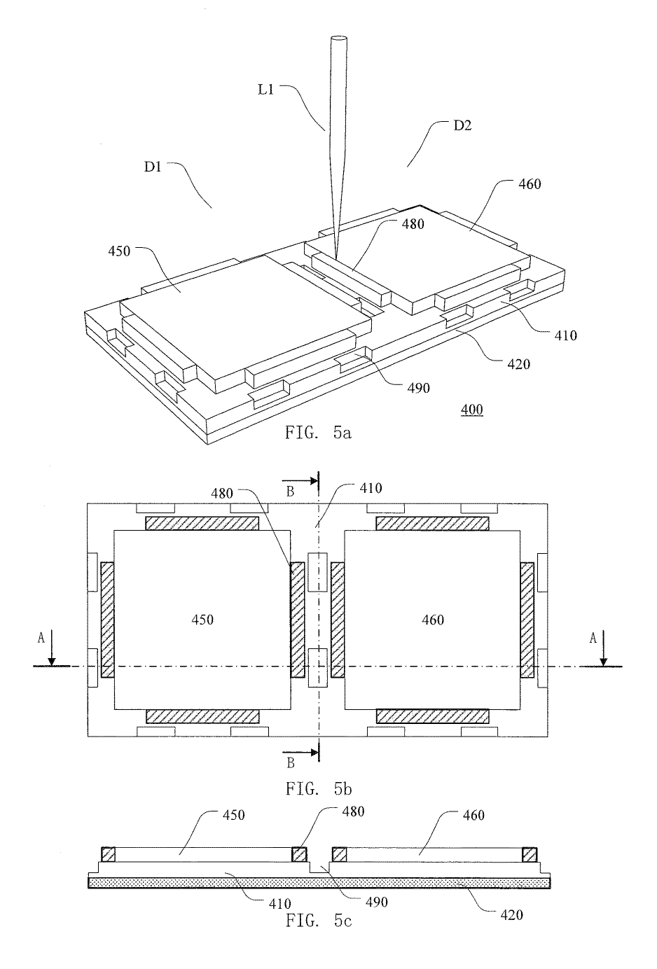

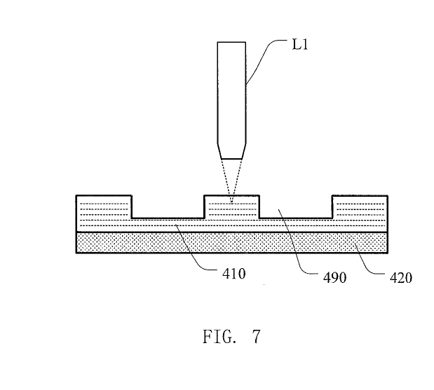

FIG. 5a to FIG. 5c illustrate schematic diagrams of a wafer structure according to a third embodiment of the disclosure in a perspective view, in a top view and in a cross-sectional view, respectively. The cross sectional view shown in FIG. 5b is taken along the line AA indicated in the cross-sectional view shown in FIG. 5c, and the cross sectional view shown in FIG. 7 is taken along the line BB.

As illustrated as FIG. 5a to FIG. 5c, the wafer structure 400 comprises a semiconductor substrate 410 with a plurality of functional layers 450, 460 and 480 on its first surface, and an adhesive film 420 on the second surface of the semiconductor substrate 410, where the second surface is opposite to the first surface of the semiconductor substrate 410. The wafer structure 400 provides two dies D1 and D2 which are separated by a scribe lane, wherein the die D1 comprises the functional layer 450 and a portion of the semiconductor substrate 410, and the die D2 comprises the functional layer 460 and another portion of the semiconductor substrate 410. The functional layer 480 is used for providing a plurality of interconnections between the die D1 and the die D2.

Different from the wafer structure 100 according to the prior art shown in FIG. 1a to FIG. 1c, the wafer structure 400 of this embodiment further includes a plurality of scribing marks 490. Different from the wafer structure 300 according to the second embodiment of this invention shown in FIG. 3a to FIG. 3c, the plurality of scribing marks 490 are the trenches opened at the first surface of the semiconductor substrate 410, located between the adjacent functional layers 480 of the adjacent dies and extended in the same direction as the laser scanning Preferably, the distance between the adjacent functional layers of the adjacent dies is no less than 5 micrometers.

The other aspects of the wafer structure 400 in this embodiment are the same as the wafer structure 300 described in the second embodiment shown in FIG. 3a to FIG. 3c, thus no detailed description is repeated here.

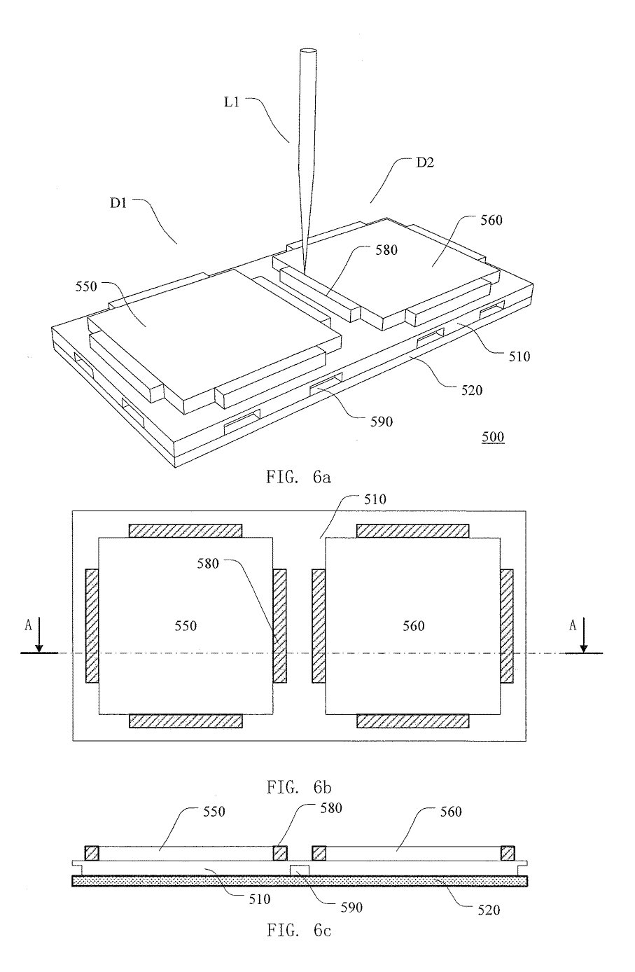

FIG. 6a to FIG. 6c illustrate schematic diagrams of a wafer structure according to a forth embodiment of the disclosure in a perspective view, in a top view and in a cross-sectional view, respectively. The cross sectional view shown in FIG. 6c is taken along the line AA indicated in the cross-sectional view shown in FIG. 6b.

As illustrated as FIG. 6a to FIG. 6c, the wafer structure 500 comprises a semiconductor substrate 510 with a plurality of functional layers 550, 560 and 580 on its first surface, and an adhesive film 520 on the second surface of the semiconductor substrate 510, where the second surface is opposite to the first surface of the semiconductor substrate 510. The wafer structure 500 provides two dies D1 and D2 which are separated by a scribe lane, wherein the die D1 comprises the functional layer 550 and a portion of the semiconductor substrate 510, and the die D2 comprises the functional layer 560 and another portion of the semiconductor substrate 510. The functional layer 580 is used for providing a plurality of interconnections between the die D1 and the die D2.

Different from the wafer structure 100 according to the prior art shown in FIG. 1a to FIG. 1c, the wafer structure 500 of this embodiment further includes a plurality of scribing marks 590. Different from the wafer structure 400 according to the disclosure shown in FIG. 5a to FIG. 5c, the plurality of scribing marks 590 are the trenches opened at the second surface of the semiconductor substrate 510, located between the adjacent functional layers 580 of the adjacent dies and extended in the same direction as the laser scanning Preferably, the distance between the adjacent functional layers of the adjacent dies is no less than 5 micrometers.

The other aspects of the wafer structure 500 in this embodiment are the same as the wafer structure 400 described in the third embodiment shown in FIG. 5a to FIG. 5c, thus no detailed description is repeated here.

FIG. 7 illustrates a schematic diagram of a wafer structure under laser irradiation according to a third embodiment of the disclosure in a cross-sectional view. As shown in FIG. 7, along the scanning path, the laser L1 always is focused inside the semiconductor substrate 410. Therefore, the initial cracks are continuous, shown as the dashed line.

During laser irradiating, the laser scanning can be performed along the scribe lane for a plurality of times, for focusing the laser L1 at different depths in the semiconductor substrate 410 respectively, thereby forming the initial cracks with a plurality of different depths extending along the scribe lane. In this embodiment, the initial cracks with at least one depth can meet the scribing marks 490, thereby a complete path is formed by the connections among them. Preferably, the scribing marks 490 can control the singulated positions of the adjacent dies accurately.

Furthermore, the present inventor have noticed that during laser cutting, the dicing machine moves the laser on the wafer step by step, thus the alignment accuracy is reduced by the accumulation of errors. Therefore, if the laser beam is deviated from the center of the scribe lane, it cannot singulate the adjacent dies during the expansion of the adhesive film, because the width of the scribing marks is narrow and the deviation degree of the laser beam goes beyond the preferred width range, for example, 5 micrometers, that is +/−2.5 micrometers. Thereby there is no connection between the modified layer and the scribe marks, thus no completed dicing initial defect will be formed.

If undivided bad dies are produced from the plurality of dies on the wafer because of laser beam deviation, then this portion of the dies will be discarded and cannot be put into the subsequent production process. If the undivided bad dies are not identified during the production, then the automatic production line will be misused, bringing about the dies generated in the form of double die or even multiple die and then packaged into products during the subsequent packaging process. Finally, in the case of MEMS microphones, it will cause the problem that both of the packaging board and the supported IC chip on it should be discarded, leading to higher costs.

To ensure that every laser beam is focused at the middle of the scribe lane, the frequency of self-testing alignment accuracy in the dicing equipment needs to be increased. That is, the correction for eliminating the accumulated alignment errors should be performed every time after several repeated movements. However, during the production process, it is usually needed to move the laser beam for dozens of times repeatedly. As a result, the working hour of the dicing machine increases tenfold, posing great pressure on the productivity and the depreciation of equipment, and also leading to higher production costs and die costs.

Therefore, in the following embodiments with further improvements, it is desirable to expand the width of the scribing mark, and still maintain the mechanical strength of the wafer structure.

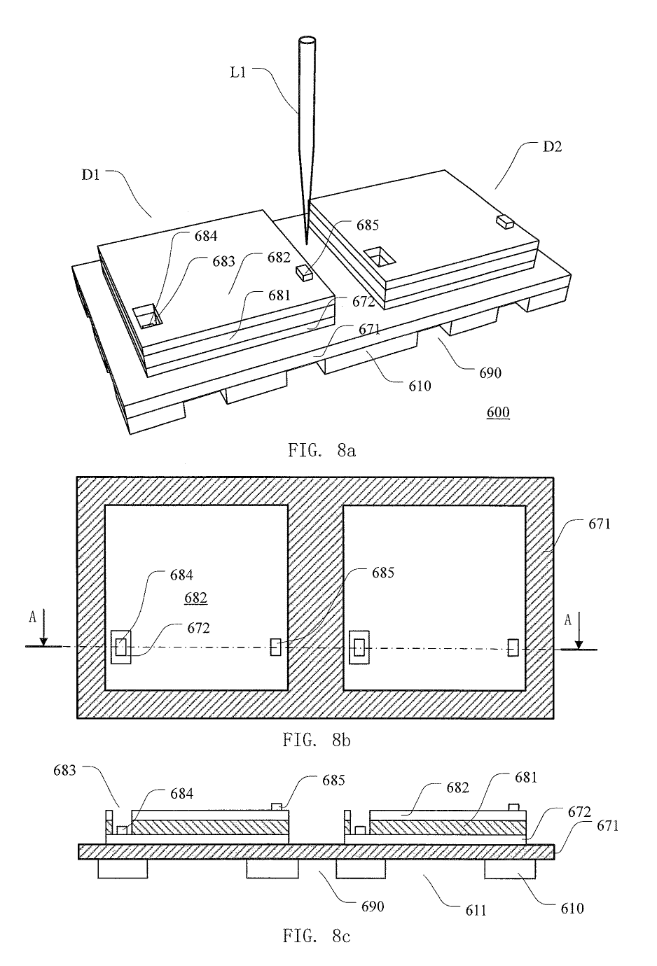

FIG. 8a to FIG. 8c is a perspective view, a top view and a cross-sectional view respectively showing a wafer structure after forming the scribing marks, according to an embodiment of the disclosure. The cross sectional view shown in FIG. 8b is taken along the line AA indicated in the cross-sectional view shown in FIG. 8c.

The wafer structure 600 includes two dies D1 and D2 separated by the scribe lane. In this embodiment, the die D1 and the die D2 with the same structure are MEMS microphones respectively. Hereinafter only the die D1 is taken as an example to show the wafer structure.

The wafer structure 600 comprises a semiconductor substrate 610, and followings successively formed on the semiconductor substrate 610: a first sacrificial layer 671, a diaphragm 672, a second sacrificial layer 681 and a back electrode 682. In the region related to the die D1, take the first sacrificial layer 671, the diaphragm 672, the second sacrificial layer 681 and the back electrode 682 as the at least one first functional layer, for forming the structure of the MEMS microphone. In the example of taking the die D1 and D2 as MEMS microphones, an opening 283 which reaches the diaphragm 672 is formed in the second sacrificial layer 681 and the back electrode 682. Through the opening 283, an first electrode 684 is formed, having an electric connection with the diaphragm 672. A second electrode 685 is formed on the surface of the back electrode 682. The region between the die D1 and the die D2 is called a scribe lane. The first sacrificial layer 671 is extended to the scribe lane as a second functional layer. An additional second functional layer may be included in the scribe lane for providing the connection between the die D1 and the die D2.

During the wafer testing, the functional layers in the scribe lane can provide connections among the plurality of dies to implement a testing on dies in series or in parallel. After completing the wafer testing, separate the die D1 and the die D2 by the laser cutting, then package them into singulated products.

Different from the wafer structure 100 according to the prior art shown in FIG. 1a to FIG. 1c, the wafer structure 600 of this embodiment further includes a plurality of scribing marks 690, which are the openings formed in the semiconductor substrate 610. The plurality of scribing marks 690 are located below the first sacrificial layer 671, and extended in the same direction as the laser scanning.

In one example, the scribing marks may be formed by etching. For defining the position of the openings, a photoresist mask may be used for forming the openings on the mask. Then, an exposed portion of the semiconductor substrate is removed through the photoresist mask by dry etching, such as ion milling etching, plasma etching, reactive ion etching, laser ablation, or by wet etching using an etching solution, so as to form the openings as the scribing marks 690. After etching, the photoresist mask is removed by ashing or dissolution with a solvent.

In the above etching, an acoustic cavity 611 of the MEMS microphone may be formed with the scribing marks 690 simultaneously, wherein, for example, the first sacrificial layer 671 is used as the etch stop. The scribing marks 690 and the acoustic cavity 611 are formed at the same etching step, therefore reducing the process costs.

The thickness of the first sacrificial layer 671 is in a range between 0.5 micrometer and 5 micrometers. If the first sacrificial layer 671 is too thin, it may be penetrated during etching, leading to damages on the etching machine. On the contrary, if the first sacrificial layer 671 is too thick, not only the process cost will be increased, but also the semiconductor substrate 610 will become deformed due to the excessive stress produced by the first sacrificial layer 671.

Preferably, the plurality of the scribing marks 690 have an overall length along the scribe lane, the proportion of which in a length of the scribe lane is no than 50%. If the scribing marks 690 are too long, the strength of the wafer structure 600 may be reduced. The wafer structure 600 may be broken during transportation.

Preferably, the width of the scribing marks 690 is about from 5 micrometers to 120 micrometers, which allowing for large alignment errors during laser cutting. If the width of the scribing marks 690 is too small, it will result in laser alignment difficulties. If the width of the scribing marks 690 is too large, the strength of the wafer structure 600 may be reduced. The wafer structure 600 may be broken during transportation

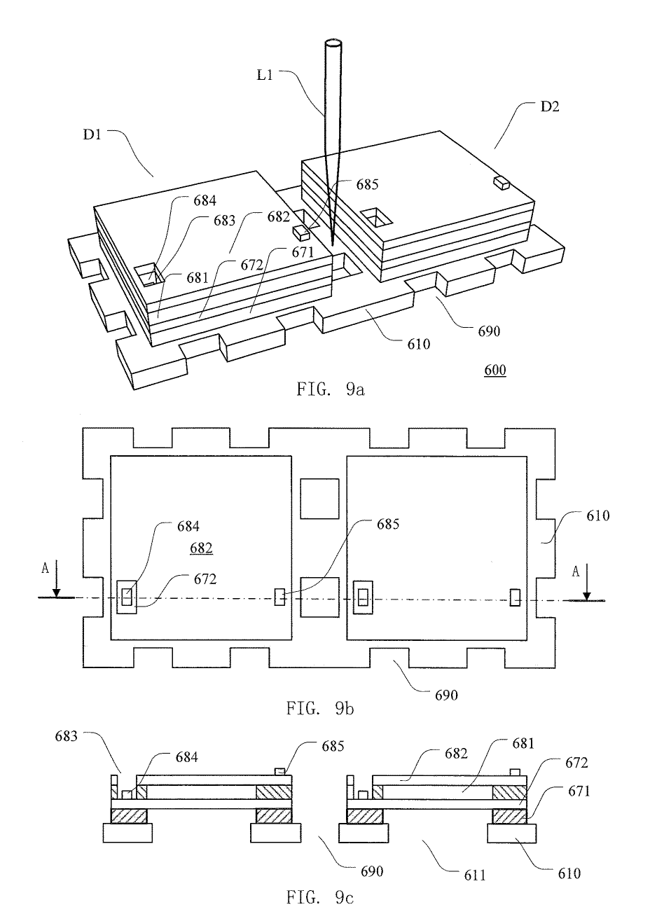

FIG. 9a to FIG. 9c are a perspective view, a top view and a cross-sectional view of a wafer structure after releasing structure, according to a fifth embodiment of the disclosure. In order to release the diaphragm 672, for example, the exposed portion of the first sacrificial layer 671 and the exposed portion of the second sacrificial layer 681 are removed by selectivity etching described above. The cross sectional view shown in FIG. 9b is taken along the line AA indicated in the cross-sectional view shown in FIG. 9c.

In an example, the top surface of the wafer structure 600 is covered by a photoresist mask. The etching solution will enter the acoustic cavity 611 from the bottom surface of the wafer structure 600. The exposed portion of the first sacrificial layer 671 is etched by the etching solution so as to expose the middle portion at the bottom surface of the diaphragm 672. In the peripheral portion of the diaphragm 672, the remaining portion of the first sacrificial layer 671 forms the anchor of the MEMS microphone. Furthermore, an additional opening can be formed in the middle portion of the diaphragm 672, and the etching solution may further reach the second sacrificial layer 681 through the additional opening. The exposed portion of the second sacrificial layer 681 is further etched by the etching solution, so as to expose the middle portion at top surface of the diaphragm 672.

In another example, the structure may be released by etching for two times. The first etching is similar to the above example, wherein the exposed portion of the first sacrificial layer is removed through the acoustic cavity 611. However, different from the above example, an additional opening can be formed in the back electrode 682, and the etching solution may further reach the second sacrificial layer 681. The exposed portion of the second sacrificial layer 681 is further etched by the etching solution, so as to expose the middle portion at top surface of the diaphragm 672.

After releasing the structure, as shown FIG. 9c, neither the middle portion at the top surface nor the middle portion at the bottom surface of the diaphragm 672 is attached to the sacrificial layer. The diaphragm 672 vibrates freely by the acoustic wave transmitted through the acoustic cavity.

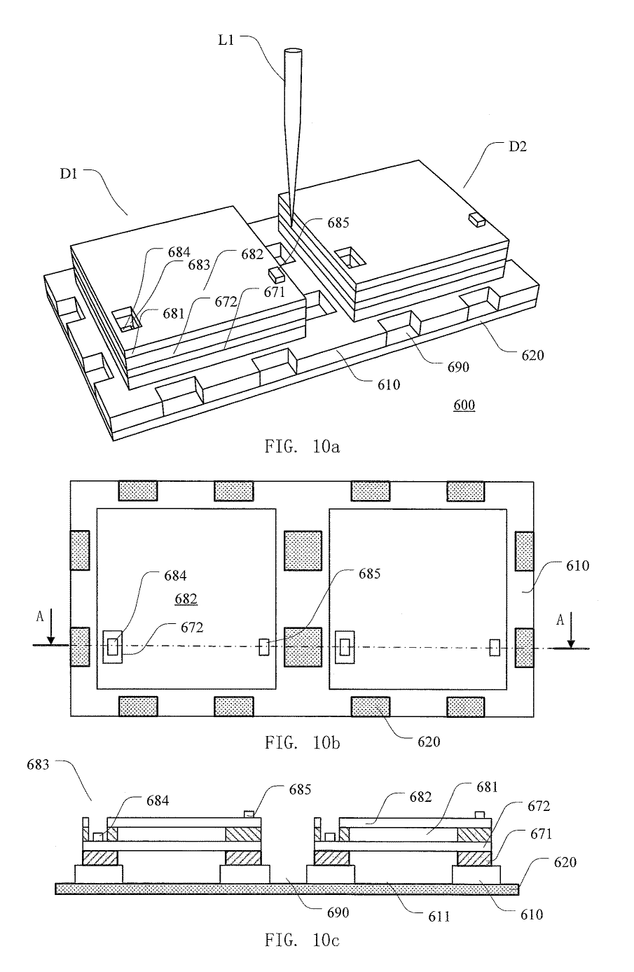

FIG. 10a to FIG. 10c are a perspective view, a top view and a cross-sectional view of a wafer structure under laser irradiation according to an embodiment of the disclosure. The cross sectional view shown in FIG. 10b is taken along the line AA indicated in the cross-sectional view shown in FIG. 10c.

During the laser cutting, the initial cracks are generated in a modified layer, by focusing the laser L1 inside the semiconductor substrate 610 from the top side of the wafer structure 600. The laser L1 scans along the scribing line. In this embodiment, the opening depth of the scribing marks 690 reaches the same level as the initial cracks formed by the laser L1. A complete path can still be formed by the connections between the discontinuous initial cracks and the openings of the scribe marks 690.

The wafer structure 600 is attached to the adhesive film 620 for example by adhesion. While expanding the adhesive film 620, the initial cracks and the scribing marks 690 provide an extension path of cracks. Thus, the die D1 and the die D2 are separated from each other.

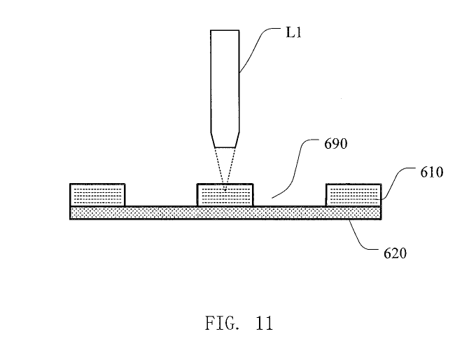

FIG. 11 illustrates a schematic diagram of a wafer structure under laser irradiation according to a fifth embodiment of the disclosure in a cross-sectional view. As shown in FIG. 11, along the scanning path, the laser L1 is focused inside the semiconductor substrate 610. Since the scribing marks 690 penetrate the semiconductor substrate 610, the initial cracks are discontinuous, shown as the dashed line.

During laser irradiating, the laser scanning can be performed along the scribe lane for a plurality of times, for focusing the laser L1 at different depths in the semiconductor substrate 610 respectively, thereby forming the initial cracks with a plurality of different depths extending along the scribe lane. In this embodiment, the initial cracks and the scribing marks 690 form a complete path. Preferably, the scribing marks 690 can control the singulated positions of the adjacent dies accurately.

In this embodiment, the width of the scribing marks 690 is about 5 micrometers to 120 micrometers, thereby during laser cutting, a large alignment error may be allowed and the mechanical strength of the wafer structure will be maintained.

The wafer structure according to the above embodiment can be applied to various types of dies. Before performing the laser cutting, the at least one second functional layer provides the connections among the plurality of dies in order to implement a testing on the plurality of dies connected in series or in parallel. After the wafer testing, the plurality of the dies are singulated by the complete path which is generated among the plurality of the scribing marks and the initial cracks causing by the laser scanning process, then the singulated dies will be assembled into individual products.

In the above description, details on the well-known steps and the well-known structural elements are not provided. Nevertheless, one skilled person will appreciate that the layers and regions having desired shapes can be formed by various approaches well known in the field. Moreover, one skilled person may propose a process completely different from the above processes for providing the same structure. Furthermore, although various embodiments are described in different paragraphs, it does not mean that technical approaches in different embodiments cannot be combined advantageously.

Reference has been made in detail to particular embodiments of the disclosure. It should be understood that they have been presented by way of example, and not limitation on the protection scope of the present disclosure. The protection scope is defined by the attached claims and their equivalences. One skilled person will readily recognize that various modifications and changes may be made to the present disclosure, without departing from the true scope of the present disclosure.

1. A wafer structure, which is used for forming a plurality of dies, comprising:
a semiconductor substrate;
at least one first functional layer and at least one second functional layer at a first surface of said semiconductor substrate, wherein said at least one second functional layer is located in a scribe lane of said wafer; and
a plurality of scribing marks in said scribe lane,
wherein said plurality of dies each include said at least one first functional layer and a portion of said semiconductor substrate,
said plurality of scribing marks are used for singulating adjacent ones of said plurality of dies during a laser cutting process.

2. The wafer structure according to claim 1, wherein said semiconductor substrate has a first surface and a second surface opposite to said first one, said at least one first functional layer and said at least one second functional layer are provide at said first surface of said semiconductor substrate,
said plurality of scribing marks are selected from said group consisting of a trench opened on said first surface, a trench opened at said second surface, or an opening extending from said first surface to said second surface.

3. The wafer structure according to claim 1, wherein said at least one second functional layer provides mechanical and/or electric connection between said adjacent ones of said plurality of dies.

4. The wafer structure according to claim 1, wherein said plurality of scribing marks are located below said at least one second functional layer.

5. The wafer structure according to claim 1, wherein said plurality of scribing marks are located between adjacent ones of said at least one second functional layer of adjacent ones of said plurality of dies.

6. The wafer structure according to claim 1, wherein said adjacent ones of said at least one second functional layer in said adjacent ones of said plurality of dies are separated from each other with a distance no less than 5 micrometers.

7. The wafer structure according to claim 2, wherein said trenches extend in the same direction as a laser scanning direction.

8. The wafer structure according to claim 7, wherein said trenches have a length no less than a dimension of respective one of said at least one second functional layer along said laser scanning direction.

9. The wafer structure according to claim 7, wherein said trenches have a width less than 5 micrometers.

10. The wafer structure according to claim 7, wherein said trenches reach the same depth as a focus depth of said laser during scanning in said semiconductor substrate.

11. The wafer structure according to claim 2, wherein said at least one first functional layer and said at least one second functional layer includes a common first sacrificial layer.

12. The wafer structure according to claim 11, wherein said opening is located below said first sacrificial layer.

13. The wafer structure according to claim 12, wherein said first sacrificial layer has a thickness in a range between 0.5 micrometer and 5 micrometers.

14. The wafer structure according to claim 12, wherein said openings have an overall length along said scribe lane, said proportion of which in a length of said scribe lane is no more than 50%.

15. The wafer structure according to claim 12, wherein said openings have a width in a range between 5 micrometers and 120 micrometers.

16. The wafer structure according to claim 12, wherein said at least one first functional layer is separated by said scribe lane.

17. The wafer structure according to claim 12, wherein said plurality of dies are MEMS microphones respectively, and said at least one second functional layer further includes a second sacrificial layer, a diaphragm and a back electrode, said first sacrificial layer provides an anchor for securing said diaphragm, said second sacrificial layer separating said diaphragm from said back electrode, and in said semiconductor substrate, and an acoustic cavity is formed in said semiconductor substrate and extends from said second surface to said diaphragm.

18. The wafer structure according to claim 17, wherein said scribing marks are formed simultaneously with said acoustic cavity.

19. A processing method of a wafer structure, comprising:
forming a plurality of dies, each of which includes a portion of said semiconductor substrate and respective one of at least one first functional layer formed at a first surface of said semiconductor substrate;
forming at least one second functional layer in said scribe lane for providing mechanical and/or electric connection between adjacent ones of said plurality of dies;
forming scribing marks in said scribe lane; and
performing laser cutting along said scribe lane.

20. The processing method according to claim 19, wherein said plurality of scribing marks include a plurality of trenches which are opened at said first surface, wherein said second functional layer is formed after said plurality of scribing marks so that said at least one second functional layer covers at least a portion of said plurality of trenches respectively.

21. The processing method according to claim 19, said plurality of scribing marks include a plurality of trenches which are opened at a second surface of said semiconductor substrate, wherein said second surface is opposite to said first surface.

22. The processing method according to claim 19, wherein said at least one first functional layer and said at least one second functional layer includes a common first sacrificial layer, said plurality of scribing marks include a plurality of openings which are formed by etching to extend from said first surface to said second surface of said semiconductor substrate while said first sacrificial layer is used as an etch stop.

23. The processing method according to claim 22, wherein when forming said plurality of scribing marks, an acoustic cavity is formed simultaneously in said semiconductor substrate by etching while said first sacrificial layer is used as an etch stop.

24. The processing method according to claim 19, wherein said laser cutting comprises:
attaching an adhesive film to said second surface of said semiconductor substrate;
performing laser scanning along said scribing line on said first surface of said semiconductor substrate so that a modified layer is formed in said semiconductor substrate; and
expanding said adhesive film to separate adjacent ones of said plurality of dies.

25. The processing method according to claim 24, wherein said laser cutting is performed along an extension direction of said plurality of scribing marks.

26. The processing method according to claim 24, wherein said laser scanning is performed along said scribe lane for several times, to have different focus depths in said semiconductor substrate each time.

27. The processing method according to claim 24, wherein at least one of said different focus depths reaches a depth of said plurality of scribing marks.

28. The processing method according to claim 24, wherein an modified layer is formed by laser scanning for providing initial cracks which form a complete path with said plurality of said scribing marks.

29. The processing method according to claim 19, before said step of forming said at least one second functional layer and said step of performing laser cutting, further comprising testing said wafer while said at least one second functional layer provides connections among said plurality of dies in series or in parallel.
